(19) United States
(12) Patent Application Publication
(10) Pub. No.: US 2025/0040417 A1
(43) Pub. Date: Jan. 30, 2025

(54) DISPLAY DEVICE

(71) Applicant: Samsung Display Co., LTD., Yongin-si (KR)

(72) Inventors: Seung Yeon JEONG, Yongin-si (KR); Oh Jeong KWON, Yongin-si (KR); Hyeo Ji KANG, Yongin-si (KR); Tae Ho KIM, Yongin-si (KR); Mi Hwa LEE, Yongin-si (KR); Hong Yeon LEE, Yongin-si (KR)

(73) Assignee: Samsung Display Co., LTD., Yongin-si (KR)

(21) Appl. No.: 18/615,642

(22) Filed: Mar. 25, 2024

(30) Foreign Application Priority Data
Jul. 26, 2023 (KR) 10-2023-0097677

(51) Int. Cl. H10K 59/80; H10K 59/127; H10K 59/40; H10K 102/00

(52) U.S. Cl. CPC H10K 59/8792; H10K 59/1275; H10K 59/873; H10K 59/40; H10K 2102/351

(57) ABSTRACT

A display device includes a light emitting element disposed on a substrate. A capping layer, an antireflection layer, and an encapsulation layer are sequentially disposed on the light emitting element. The capping layer includes a first capping layer disposed on the light emitting element, and a second capping layer disposed on the first capping layer and having a refractive index greater than a refractive index of the first capping layer. A thickness of the first capping layer is in a range of about 20 Å to about 400 Å, and a thickness of the second capping layer is in a range of about 60 Å to about 400 Å.

### CROSS REFERENCE TO RELATED APPLICATION(S)

This application claims priority to and benefits of Korean Patent Application No. 10-2023-0097677, filed on Jul. 26, 2023, under 35 U.S.C. § 119, the entire content of which are incorporated herein by reference.

### BACKGROUND

### 1. Technical Field

An embodiment relates to a display device.

### 2. Description of the Related Art

A display device may display an image. As external light is reflected on a surface of the display device, display quality of the display device may be degraded. In order to solve this problem, a polarizing film, a color filter, and the like are used in the display device. Research has been conducted to suppress or minimize the reflection of the external light.

### SUMMARY

Embodiments provide a display device capable of reducing or minimizing external light reflection.

However, embodiments of the disclosure are not limited to those set forth herein. The above and other embodiments will become more apparent to one of ordinary skill in the art to which the disclosure pertains by referencing the detailed description of the disclosure given below.

According to embodiments, a display device includes a light emitting element disposed on a substrate, a capping layer disposed on the light emitting element, an antireflection layer disposed on the capping layer, and an encapsulation layer disposed on the antireflection layer. The capping layer includes a first capping layer disposed on the light emitting element, and a second capping layer disposed on the first capping layer and having a refractive index greater than a refractive index of the first capping layer. A thickness of the first capping layer may be in a range of about 20 Å to about 400 Å, and a thickness of the second capping layer may be in a range of about 60 Å to about 400 Å.

The antireflection layer may include ytterbium or bismuth, and the first capping layer and the second capping layer may include an inorganic material.

A total thickness of the capping layer may be in a range of about 400 Å to about 450 Å.

The refractive index of the second capping layer may be greater than the refractive index of the first capping layer by about 0.1 or more, the refractive index of the first capping layer may be in a range of about 1.2 to about 1.7, and the refractive index of the second capping layer may be in a range of about 1.7 to about 2.2.

The thickness of the first capping layer may be in a range of about 180 Å to about 300 Å, and the thickness of the second capping layer may be in a range of about 120 Å to about 240 Å.

A total thickness of the first capping layer and the second capping layer may be in a range of about 400 Å to about 450 Å.

The capping layer may further include a third capping layer disposed between the second capping layer and the antireflection layer and having a refractive index less than the refractive index of the second capping layer, and a thickness of the third capping layer may be in a range of about 20 Å to about 300 Å.

The refractive index of the second capping layer may be greater than the refractive index of each of the first capping layer and the third capping layer by about 0.1 or more, the refractive index of the first capping layer may be in a range of about 1.2 to about 1.7, the refractive index of the second capping layer may be in a range of about 1.7 to about 2.2, and the refractive index of the third capping layer may be in a range of about 1.2 to about 1.7.

The thickness of the first capping layer may be in a range of about 180 Å to about 300 Å, the thickness of the second capping layer may be in a range of about 60 Å to about 180 Å, and the thickness of the third capping layer may be in a range of about 20 Å to about 150 Å.

A total thickness of the first capping layer, the second capping layer, and the third capping layer may be in a range of about 400 Å to about 450 Å.

The light emitting element may include a first electrode, a light emitting layer disposed on the first electrode, and a second electrode disposed on the light emitting layer, and the capping layer may be disposed between the second electrode and the antireflection layer.

According to embodiments, a display device includes a light emitting element disposed on a substrate, a capping layer disposed on the light emitting element, an antireflection layer disposed on the capping layer, and an encapsulation layer disposed on the antireflection layer. The capping layer includes a first capping layer disposed on the light emitting element, a second capping layer disposed on the first capping layer and having a refractive index less than a refractive index of the first capping layer, and a third capping layer disposed on the second capping layer and having a refractive index greater the refractive index of the second capping layer. A thickness of the first capping layer may be in a range of about 20 Å to about 300 Å, a thickness of the second capping layer may be in a range of about 60 Å to about 400 Å, and a thickness of the third capping layer may be in a range of about 20 Å to about 300 Å.

The refractive index of the second capping layer may be less than the refractive index of each of the first capping layer and the third capping layer by about 0.1 or more, the refractive index of the first capping layer may be in a range of about 1.7 to about 2.2, the refractive index of the second capping layer may be in a range of about 1.2 to about 1.7, and the refractive index of the third capping layer may be in a range of about 1.7 to about 2.2.

The thickness of the first capping layer may be in a range of about 20 Å to about 240 Å, the thickness of the second capping layer may be in a range of about 120 Å to about 360 Å, and the thickness of the third capping layer may be in a range of about 20 Å to about 200 Å.

A total thickness of the capping layer may be in a range of about 350 Å to about 450 Å.

The light emitting element may include a first electrode, a light emitting layer disposed on the first electrode, and a second electrode disposed on the light emitting layer, and the capping layer may be disposed between the second electrode and the antireflection layer.

According to embodiments, a display device includes a light emitting element disposed on a substrate, a first capping layer disposed on the light emitting element, an antireflection layer disposed on the first capping layer, and an encapsulation layer disposed on the antireflection layer. A refractive index of the first capping layer may be in a range of about 1.2 to about 1.7, and a thickness of the first capping layer may be in a range of about 200 Å to about 600 Å.

A thickness of the first capping layer may be in a range of about 360 Å to about 480 Å.

The light emitting element may include a first electrode, a light emitting layer disposed on the first electrode, and a second electrode disposed on the light emitting layer, and the first capping layer may be disposed between the second electrode and the antireflection layer.

The display device may further include a second capping layer disposed on at least one of first and second surfaces of the first capping layer, a refractive index of the second capping layer may be greater than the refractive index of the first capping layer by about 0.1 or more, and the refractive index of the second capping layer may be in a range of about 1.7 to about 2.2.

Details of other embodiments are included in the detailed description and drawings.

The display device according to embodiments may include the capping layer and the antireflection layer disposed between the light emitting element and the encapsulation layer, the capping layer may include a low refractive index capping layer having a refractive index of about 1.2 to about 1.7, and the thickness of the capping layer may be in a range of about 200 Å to about 600 Å. For example, the capping layer may cancel external light using a phase difference of the external light reflected from the capping layer. Accordingly, reflectivity of the external light may be reduced, and display quality of the display device may be improved.

An effect according to embodiments is not limited by the contents illustrated above, and more various effects are included in the description.

### BRIEF DESCRIPTION OF THE DRAWINGS

The above and other features of the disclosure will become more apparent by describing in further detail embodiments thereof with reference to the accompanying drawings, in which:

FIG. 1 is a schematic diagram illustrating a display device according to embodiments;

FIG. 2 is a schematic cross-sectional view illustrating an embodiment of the display device of FIG. 1;

FIG. 3 is a schematic cross-sectional view illustrating an embodiment of a display unit included in the display device of FIG. 1;

FIG. 4 is a schematic cross-sectional view illustrating a function of a capping layer included in the display unit of FIG. 3;

FIG. 5 is a schematic cross-sectional view illustrating an embodiment of a sensor unit included in the display device of FIG. 1;

FIG. 6 is a schematic cross-sectional view illustrating an embodiment of the display device of FIG. 1;

FIG. 7 is a schematic cross-sectional view illustrating an embodiment of the capping layer included in the display device of FIG. 6;

FIG. 8 is a schematic diagram illustrating light emission efficiency according to a thickness of the capping layer of FIG. 7;

FIG. 9 is a schematic diagram illustrating reflectivity according to the thickness of the capping layer of FIG. 7;

FIG. 10 is a schematic cross-sectional view illustrating an embodiment of the capping layer included in the display device of FIG. 6;

FIGS. 11 and 12 are schematic diagrams illustrating light emission efficiency according to a thickness of the capping layer of FIG. 10;

FIGS. 13 and 14 are schematic diagrams illustrating reflectivity according to the thickness of the capping layer of FIG. 10;

FIG. 15 is a schematic cross-sectional view illustrating an embodiment of the capping layer included in the display device of FIG. 6;

FIGS. 16 and 17 are schematic diagrams illustrating light emission efficiency according to a thickness of the capping layer of FIG. 15;

FIGS. 18 and 19 are schematic diagrams illustrating reflectivity according to the thickness of the capping layer of FIG. 15;

FIG. 20 is a schematic cross-sectional view illustrating an embodiment of the capping layer included in the display device of FIG. 6; and

FIG. 21 is a schematic diagram illustrating light emission efficiency and reflectivity according to a thickness of the capping layer of FIG. 20.

### DETAILED DESCRIPTION OF THE EMBODIMENT

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element (or a layer) is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another clement or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein are interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, a display device according to an embodiment is described with reference to drawings related to embodiments.

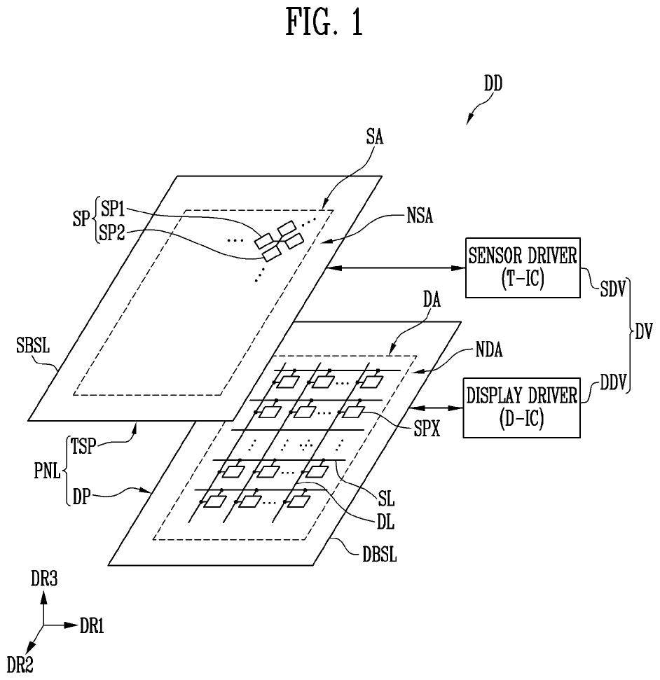

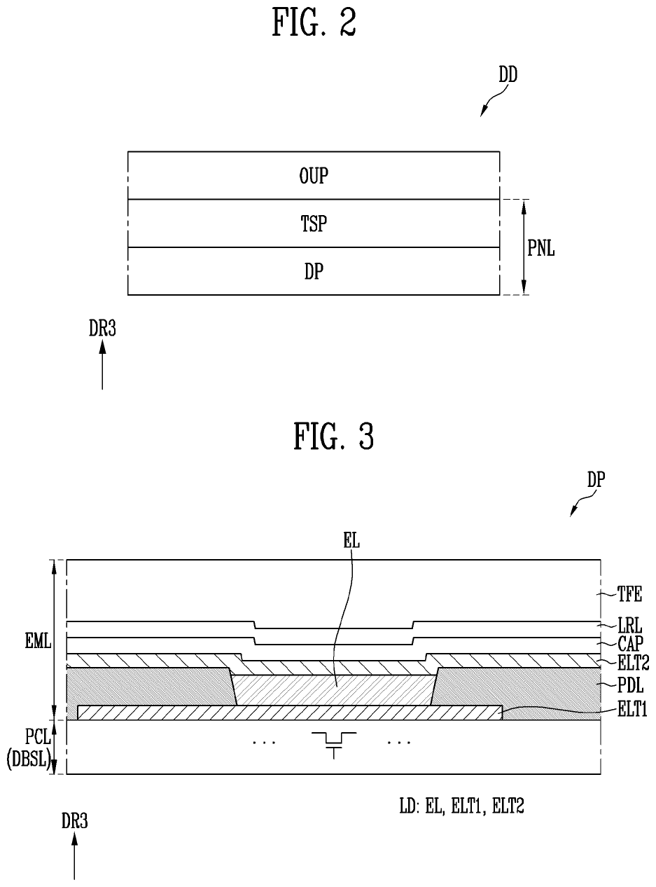

FIG. 1 is a schematic diagram illustrating a display device according to embodiments. FIG. 2 is a schematic cross-sectional view illustrating an embodiment of the display device of FIG. 1.

Referring to FIGS. 1 and 2, the display device DD may be a device that displays an image, and may be used as a display screen for various products such as a television, a notebook computer, a monitor, a billboard, Internet of things (IOT) as well as a portable electronic device such as a mobile phone, a smart phone, a tablet personal computer (PC), a smart watch, a watch phone, a mobile communication terminal, an electronic notebook, an electronic book, a portable multimedia player (PMP), a navigation device, and an ultra mobile PC (UMPC).

The display device DD may include a panel PNL and a driving circuit unit DV for driving the panel PNL. The display device DD may further include an outer portion OUP.

The panel PNL may include a display unit DP for displaying an image and a sensor unit TSP capable of sensing a user input (for example, a touch input). The display unit DP may be referred to as a display panel. The sensor unit TSP may be referred to as a sensing panel or a touch sensor.

The panel PNL may include sub-pixels SPX and sensing electrodes SP. According to an embodiment, the sub-pixels SPX may display an image by a display frame period. The sensing electrodes SP may sense an input (for example, a touch input) of a user by a sensing frame period. The sensing frame period and the display frame period may be independent of each other or may be different from each other. The sensing frame period and the display frame period may be synchronized or asynchronous with each other.

The sensor unit TSP including the sensing electrodes SP may obtain information on the touch input of the user. According to an embodiment (for example, a mutual capacitance method), the sensing electrodes SP may include a first sensing electrode SP1 providing a first sensing signal and a second sensing electrode SP2 providing a second sensing signal. According to an embodiment, the first sensing electrode SP1 may be a transmitter (Tx) pattern electrode, and the second sensing electrode SP2 may be a receiver (Rx) pattern electrode. According to an embodiment, the information on the touch input (or a touch event) may mean information including a position or the like of a touch that is requested by the user.

However, the sensing electrodes SP are not limited thereto. For example, according to an embodiment (for example, a self-capacitance method), the sensing electrodes SP may be implemented as one type of sensing electrodes without distinction between the first sensing electrode SP1 and the second sensing electrode SP2.

The display unit DP may include a display base layer DBSL (e.g., a first base layer, or a substrate) and the sub-pixels SPX provided on the display base layer DBSL. The sub-pixels SPX may be disposed in a display area DA. The sub-pixels SPX may form a pixel, e.g., a single pixel, or a pixel unit.

The display base layer DBSL (or the display device DD) may include the display area DA in which an image is displayed and a non-display area NDA outside the display arca DA. According to an embodiment, the display area DA may be disposed in a central area of the display unit DP, and the non-display area NDA may be disposed adjacent to a periphery of the display area DA.

The display base layer DBSL may be a base substrate or a base member for supporting the display device DD. The base layer may be a rigid substrate of a glass material. In another example, the base layer may be a flexible substrate, which is bendable, foldable, rollable, or the like. For example, the base layer may include an insulating material such as a polymer resin such as polyimide. However, the display base layer DBSL is not limited thereto.

Scan lines SL and data lines DL, and the sub-pixels SPX connected to the scan lines SL and the data lines DL may be disposed in the display area DA. The sub-pixels SPX may be selected by a scan signal of a turn-on level supplied from the scan lines SL, receive a data signal from the data lines DL, and emit light of a luminance corresponding to the data signal. Accordingly, an image corresponding to the data signal may be displayed in the display area DA. However, a structure, a driving method, and the like of the sub-pixels SPX are not limited.

Various lines and/or built-in circuit units connected to the sub-pixels SPX of the display area DA may be disposed in the non-display area NDA. For example, a plurality of lines for supplying various power and control signals to the display area DA may be disposed in the non-display area NDA.

The display unit DP may output visual information (for example, an image). According to an embodiment, a type/kind of the display unit DP is not limited. For example, the display unit DP may be implemented as a self-emission type display panel such as an organic light emitting display panel. However, in case that the display unit DP is implemented as a self-emission type, each pixel is not limited to a case in which only an organic light emitting element is included. For example, a light emitting element of each pixel may be formed of an organic light emitting diode, an inorganic light emitting diode, a quantum dot/well light emitting diode, or the like.

Hereinafter, for convenience of description, the disclosure is described based on an embodiment in which the display unit DP is implemented as an organic light emitting display panel.

The sensor unit TSP may include a sensor base layer SBSL and a plurality of sensing electrodes SP formed on the sensor base layer SBSL. The sensing electrodes SP may be disposed in a sensing area SA on the sensor base layer SBSL.

The sensor base layer SBSL (or the display device DD) may include the sensing area SA where a touch input or the like is sensed, and a non-sensing area NSA around the sensing area SA. According to an embodiment, the sensing area SA may overlap at least one area of the display area DA. For example, the sensing area SA may be referred as an arca corresponding to the display area DA (for example, an arca overlapping the display area DA), and the non-sensing area NSA may be referred as an area corresponding to the non-display area NDA (for example, an area overlapping the non-display area NDA). For example, in case that the touch input or the like is provided on the display area DA, the touch input may be detected through the sensor unit TSP.

The sensor base layer SBSL may include one or more insulating layers (for example, a first insulating layer INS1 in FIG. 5). For example, the first insulating layer INS1 for forming the sensor base layer SBSL may be disposed on the display unit DP to form a base for forming the sensing electrodes SP. However, an example for forming the sensor base layer SBSL is not limited.

The sensing area SA may be referred as an area capable of responding to the touch input (e.g., an active area of a sensor). For example, the sensing electrodes SP for sensing the touch input or the like may be disposed in the sensing area SA.

The sensor unit TSP may obtain information on an input provided from the user. The sensor unit TSP may recognize or sense the touch input. The sensor unit TSP may recognize or sense the touch input using a capacitive sensing method. The sensor unit TSP may sense the touch input by using a mutual capacitance method or may sense the touch input by using a self-capacitance method.

According to an embodiment, each of the first sensing electrodes SP1 may extend in a first direction DR1. The first sensing electrodes SP1 may be arranged in a second direction DR2. The second direction DR2 may be different from the first direction DR1. For example, the second direction DR2 may be a direction perpendicular to the first direction DR1. Each of the first sensing electrodes SP1 may have a form in which first cells of a relatively large area and first bridge electrodes of a relatively small area are connected to each other. The first sensing electrodes SP1 may substantially have a diamond shape. However, a shape of the first sensing electrodes SP1 is not limited.

According to an embodiment, each of the second sensing electrodes SP2 may extend in the second direction DR2. The second sensing electrodes SP2 may be arranged in the first direction DR1. Each of the second sensing electrodes SP2 may have a form in which second cells of a relatively large area and second bridge electrodes of a relatively small area are connected to each other. The second sensing electrodes SP2 may substantially have a diamond shape. However, a shape of the second sensing electrodes SP2 is not limited.

According to an embodiment, the first sensing electrodes SP1 and the second sensing electrodes SP2 may have substantially the same shape. For example, the first sensing electrodes SP1 which are the transmitter (Tx) pattern electrodes and the second sensing electrodes SP2 which are the receiver (Rx) pattern electrodes may have substantially the same shape, and thus sensing performance of the touch event may be uniformly performed within the sensing area SA.

For example, sensing lines for electrically connecting the sensing electrodes SP to the sensor driver SDV and the like may be disposed in the non-sensing area NSA of the sensor unit TSP.

The driving circuit unit DV may include the display driver DDV for driving the display unit DP and the sensor driver SDV for driving the sensor unit TSP.

The display driver DDV may be electrically connected to the display unit DP to drive the sub-pixels SPX. The sensor driver SDV may be electrically connected to the sensor unit TSP to drive the sensor unit TSP.

The outer portion OUP may be disposed substantially above the display device DD based on a thickness direction (for example, a third direction DR3) of the display base layer DBSL. The outer portion OUP may be disposed on the sensor unit TSP. Light provided from the display unit DP may pass through the outer portion OUP and may be output to an outside.

The outer portion OUP may include a light blocking layer BM to improve visibility of the display device DD. For example, the light blocking layer BM may overlap the first sensing electrodes SP1 and the second sensing electrodes SP2 forming the sensor unit TSP, to reduce a risk of damage to visibility by the first sensing electrodes SP1 and the second sensing electrodes SP2.

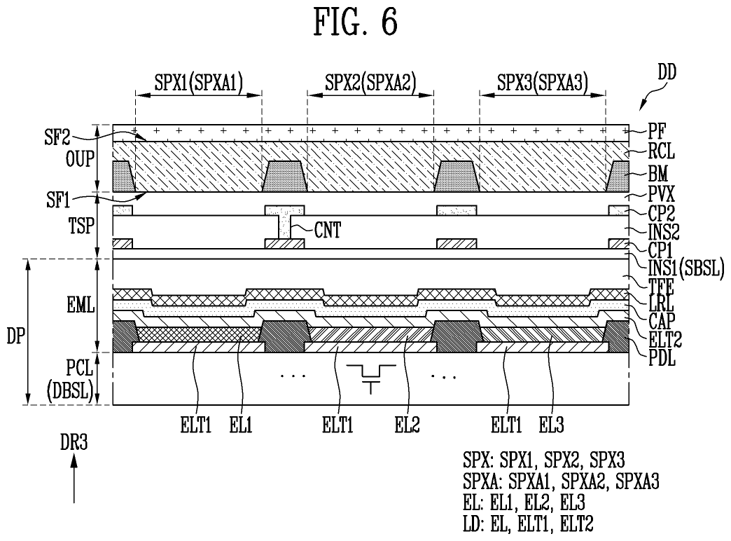

The outer portion OUP may further include a reflection control layer RCL (refer to FIG. 6) capable of improving display quality. As the reflection control layer RCL according to an embodiment is disposed, display quality of the display device DD may be improved, and reliability of a technical effect of display quality improvement may be improved. A detailed content regarding this is described later.

According to an embodiment, the outer portion OUP may protect internal configurations of the display device DD from an external influence. For example, the outer portion OUP may further include a protective film PF (refer to FIG. 6) capable of transmitting light.

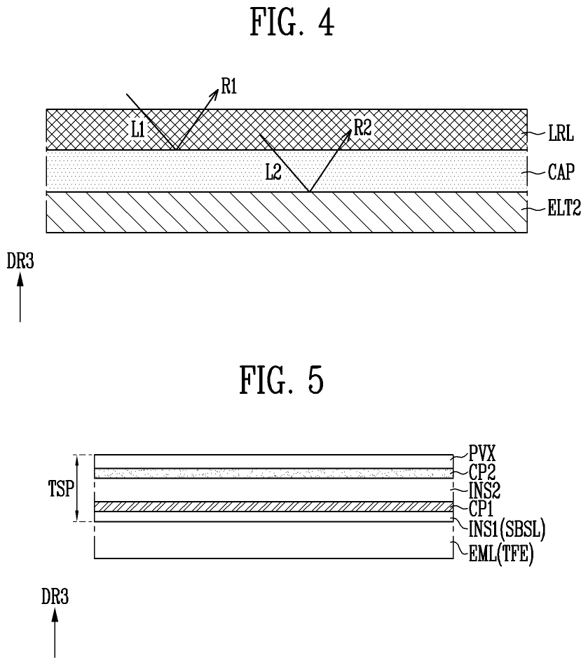

FIG. 3 is a schematic cross-sectional view illustrating an embodiment of the display unit included in the display device of FIG. 1. FIG. 4 is a schematic cross-sectional view illustrating a function of a capping layer included in the display unit of FIG. 3.

Referring to FIG. 3, the display unit DP may include a pixel circuit layer PCL and a light emitting element layer EML.

The pixel circuit layer PCL may include a pixel circuit for driving light emitting clements LD. The pixel circuit layer PCL may include the display base layer DBSL, conductive layers for forming pixel circuits, and insulating layers disposed between the conductive layers.

The pixel circuit may include a driving transistor. The pixel circuit may include a thin film transistor. The pixel circuit may be electrically connected to the light emitting elements LD to provide an electrical signal for the light emitting elements LD to emit light.

The light emitting element layer EML may be disposed on the pixel circuit layer PCL. According to an embodiment, the light emitting element layer EML may include the light emitting element LD, a pixel defining layer PDL, the capping layer CAP, an antireflection layer LRL, and an encapsulation layer TFE.

The light emitting clement LD may be disposed on the pixel circuit layer PCL. According to an embodiment, the light emitting element LD may include a first electrode ELT1, a light emitting layer EL disposed on the first electrode ELT1, and a second electrode ELT2 disposed on the light emitting layer EL. According to an embodiment, the light emitting layer EL may be disposed in an area defined by the pixel defining layer PDL. The pixel defining layer PDL may be adjacent to a periphery of the light emitting layer EL. A surface of the light emitting layer EL may be electrically connected to the first electrode ELT1, and another surface of the light emitting layer EL may be electrically connected to the second electrode ELT2.

The first electrode ELT1 may be an anode electrode for the light emitting layer EL, and the second electrode ELT2 may be a common electrode (or a cathode electrode) for the light emitting layer EL. According to an embodiment, the first electrode ELT1 and the second electrode ELT2 may include a conductive material. For example, the first electrode ELT1 may include a conductive material having a reflective property, and the second electrode ELT2 may include a transparent conductive material. However, the first electrode ELT1 and the second electrode ELT2 are not limited thereto.

The light emitting layer EL may have a thin film multilayer structure including a light generation layer. The light emitting layer EL may include a hole injection layer for injecting a hole, a hole transport layer having an excellent hole transport property and for increasing a chance of recombination of a hole and an electron by suppressing a movement of an electron that is not combined in the light generation layer, the light generation layer for emitting light by the recombination of the injected electron and hole, a hole blocking layer for suppressing a movement of a hole that is not combined in the light generation layer, an electron transport layer for smoothly transporting the electron to the light generation layer, and an electron injection layer for injecting the electron. The light emitting layer EL may emit light based on an electrical signal provided from the first electrode ELT1 and the second electrode ELT2.

According to an embodiment, the light emitting layer EL may emit light of a wavelength band. For example, the light emitting layer EL may include a first light emitting layer EL1 (refer to FIG. 6) that emits light of a first color having a first wavelength band, a second light emitting layer EL2 (refer to FIG. 6) that emits light of a second color having a second wavelength band, and a third light emitting layer EL3 (refer to FIG. 6) that emits light of a third color having a third wavelength band.

The first light emitting layer EL1 may form a first light emitting element emitting the light of the first color, the second light emitting layer EL2 may form a second light emitting clement emitting the light of the second color, and the third light emitting layer EL3 may form a third light emitting element emitting the light of the third color.

The first color may be red. For example, the first wavelength band corresponding to the first color may be a wavelength band of about 600 nm to about 750 nm. The second color may be green. For example, the second wavelength band corresponding to the second color may be in a range of about 480 nm to about 560 nm. The third color may be blue. For example, the third wavelength band corresponding to the third color may be a wavelength band of about 370 nm to about 460 nm.

According to an embodiment, the light emitting layer EL may not substantially emit light of a non-emission wavelength band. In the description, the non-emission wavelength band may be a wavelength band including a wavelength that at least does not partially overlap a wavelength band of light emitted from the light emitting layer EL.

According to an embodiment, the non-emission wavelength band may not overlap the wavelength band of the light emitted from the light emitting layer EL. For example, the non-emission wavelength band may not overlap the first wavelength band. The non-emission wavelength band may not overlap the second wavelength band. The non-emission wavelength band may not overlap the third wavelength band.

According to an embodiment, the non-emission wavelength band may include a first non-emission wavelength band and a second non-emission wavelength band. The second non-emission wavelength band may be a wavelength band greater than the first non-emission wavelength band.

For example, the first non-emission wavelength band may include a wavelength band between the third wavelength band and the second wavelength band. The first non-emission wavelength band may include a wavelength band between a peak wavelength of the third wavelength band and a peak wavelength of the second peak wavelength band. The second non-emission wavelength band may include a wavelength band between the second wavelength band and the first wavelength band. The first non-emission wavelength band may include a wavelength band between a peak wavelength of the second wavelength band and a peak wavelength of the first peak wavelength band.

According to an embodiment, the first non-emission wavelength band may be in a range of about 460 nm to about 520 nm. In another example, according to an embodiment, the first non-emission wavelength band may be in a range of about 490 nm to about 505 nm. According to an embodiment, the second non-emission wavelength band may be in a range of about 560 nm to about 620 nm. In another example, the second non-emission wavelength band may be in a range of about 585 nm to about 600 nm. However, embodiments are not limited thereto.

According to an embodiment, the reflection control layer RCL (refer to FIG. 6) capable of selectively absorbing light of the non-emission wavelength band of the light emitting layer EL may be disposed, and thus a reflectivity and a color sense of the display device DD may be improved. A detailed content regarding this is described later.

The pixel defining layer PDL may be disposed on the pixel circuit layer PCL to define a position where the light emitting layer EL is disposed. The pixel defining layer PDL may include an organic material. The organic material may include one or more of a group of acrylic resin, epoxy resin, phenol resin, polyamide resin, and polyimide resin. However, the pixel defining layer PDL is not limited thereto. For example, the pixel defining layer PDL may include an inorganic material.

The capping layer CAP may be disposed on the light emitting element LD (for example, the second electrode ELT2). The capping layer CAP may be disposed between the antireflection layer LRL and the light emitting element LD (for example, the second electrode ELT2). The capping layer CAP may protect the light emitting element LD (for example, the second electrode ELT2) from an outside (for example, from external impact). The capping layer CAP may be an insulating layer including an inorganic material. The inorganic material may include at least one of metal oxides such as silicon nitride (SiNₓ), silicon oxide (SiOₓ), silicon oxynitride (SiOₓN_{y}), and aluminum oxide (AlOₓ). However, the inorganic material is not limited thereto. According to an embodiment, the capping layer CAP may include lithium fluoride (LiF).

In an embodiment, the capping layer CAP may dissipate external light incident on the display device. For example, the capping layer CAP may cancel (or eliminate) the external light by using a phase difference of the external light reflected from the capping layer CAP. Referring to FIG. 4, for example, a portion of the external light L1 may be reflected from an upper surface of the capping layer CAP, and another potion of the external light L2 may be reflected from a lower surface of the capping layer CAP. For example, the external light may be divided into first reflected light R1 reflected from the upper surface of the capping layer CAP and second reflected light R2 reflected from the lower surface of the capping layer CAP. A phase of the first reflected light R1 and a phase of the second reflected light R2 may be opposite to each other. Accordingly, since the first reflected light R1 and the second reflected light R2 cancel each other and dissipate, the reflected external light may not be recognized or sensed from the outside. Accordingly, display quality of the display device may be improved. For example, since the external light is not reflected, the display device may effectively display a black image.

The capping layer CAP may include an insulating layer of a single layer or multiple layers.

The antireflection layer LRL (e.g., a low reflection inorganic layer, or a destructive interference layer) may be disposed on the capping layer CAP. The antireflection layer LRL may be disposed between the capping layer CAP and the encapsulation layer TFE.

The antireflection layer LRL may include an inorganic material. For example, the antireflection layer LRL may include one or more of a metal or a metal compound. For example, the metal may include one or more of aluminum (Al), silver (Ag), magnesium (Mg), chromium (Cr), titanium (Ti), nickel (Ni), gold (Au), tantalum (Ta), copper (Cu), calcium (Ca), cobalt (Co), iron (Fc), molybdenum (Mo), tungsten (W), platinum (Pt), bismuth (Bi), and ytterbium (Yb). The metal compound may include one or more of a group of silicon oxide (SiOₓ), titanium oxide (TiOₓ), zirconium oxide (ZrOₓ), tantalum oxide (TaₓO_{y}), hafnium oxide (HfOₓ), aluminum oxide (AlₓO_{y}) zinc oxide (ZnOₓ), yttrium oxide (YₓO_{y}), beryllium oxide (BcOₓ), magnesium oxide (MgOₓ), lead oxide (PbOₓ), tungsten oxide (WOₓ), bismuth oxide (BiOₓ), silicon nitride (SiNₓ), lithium fluoride (LiFₓ), calcium fluoride (CaFₓ), magnesium fluoride (MgFₓ), and cadmium sulfide (CdSₓ). One or more of the above-described materials may be selected as the antireflection layer LRL in consideration of a refractive index and an absorption coefficient. For example, the antireflection layer LRL may include ytterbium (Yb) or bismuth (Bi).

The antireflection layer LRL may reflect applied light. For example, light reflected by the antireflection layer LRL and light reflected by the capping layer CAP (or the second electrode ELT2) may interfere destructively with each other. Accordingly, an external light reflectivity of the display device DD may be reduced, and display quality and visibility of the display device DD may be improved.

The encapsulation layer TFE (or a thin film encapsulation layer) may be disposed on the antireflection layer LRL. The encapsulation layer TFE may offset (or compensate for) a step difference generated by the light emitting clement LD, the capping layer CAP, the antireflection layer LRL, and the pixel defining layer PDL. The encapsulation layer TFE may include a plurality of insulating layers covering the light emitting element LD. According to an embodiment, the encapsulation layer TFE may have a structure in which an inorganic layer and an organic layer are alternately stacked. According to an embodiment, the encapsulation layer TFE may be an encapsulation layer of a structure in which a first inorganic layer, an organic layer, and a second inorganic layer are sequentially stacked. According to an embodiment, the encapsulation layer TFE may be a thin film encapsulation layer.

FIG. 5 is a schematic cross-sectional view illustrating an embodiment of a sensor unit included in the display device of FIG. 1.

Referring to FIG. 5, the sensor unit TSP may be disposed on the light emitting element layer EML (or the encapsulation layer TFE). According to an embodiment, the sensor unit TSP may be disposed (e.g., directly disposed) on the encapsulation layer TFE. The sensor unit TSP may include the first insulating layer INS1, a first conductive pattern layer CP1, a second insulating layer INS2, a second conductive pattern layer CP2, and a protective layer PVX.

According to an embodiment, the first conductive pattern layer CP1 and the second conductive pattern layer CP2 may be patterned at a position to form the sensing electrodes SP (refer to FIG. 1). For example, a portion of each of the first conductive pattern layer CP1 and the second conductive pattern layer CP2 may form the first sensing electrode SP1, and a portion of the second conductive pattern layer CP2 may form the second sensing electrode SP2. However, embodiments are not limited thereto.

The first insulating layer INS1 may be disposed on the encapsulation layer TFE. The first insulating layer INS1 may form the sensor base layer SBSL, and may provide an area where the first conductive pattern layer CP1, the second insulating layer INS2, the second conductive pattern layer CP2, and the protective layer PVX are disposed. The first insulating layer INS1 may include an inorganic material.

The first conductive pattern layer CP1 may be disposed on the first insulating layer INS1. The second conductive pattern layer CP2 may be disposed on the second insulating layer INS2. The first conductive pattern layer CP1 and the second conductive pattern layer CP2 may be spaced apart from each other with the second insulating layer INS2 interposed therebetween.

The first conductive pattern layer CP1 and the second conductive pattern layer CP2 may include a metal layer of a single layer or multiple layers. The first conductive pattern layer CP1 and the second conductive pattern layer CP2 may include at least one of various metal materials including gold (Au), silver (Ag), aluminum (Al), molybdenum (Mo), chromium (Cr), titanium (Ti), nickel (Ni), neodymium (Nd), copper (Cu), and platinum (Pt), or an alloy thereof. According to an embodiment, the first conductive pattern layer CP1 and the second conductive pattern layer CP2 may include at least one of various transparent conductive materials including one of a silver nanowire (AgNW), indium tin oxide (ITO), indium zinc oxide (IZO), indium gallium zinc oxide (IGZO), antimony zinc oxide (AZO), indium tin zinc oxide (ITZO), zinc oxide (ZnO), tin oxide (SnO₂), carbon nano tube, and graphene.

The second insulating layer INS2 may be disposed on the first conductive pattern layer CP1. The second insulating layer INS2 may be interposed between the first conductive pattern layer CP1 and the second conductive pattern layer CP2. The protective layer PVX may be disposed on the second conductive pattern layer CP2.

The second insulating layer INS2 may include an organic material. The protective layer PVX may include an organic material. The organic material may include one or more of a group of acrylic resin, methacrylic resin, polyisoprene, vinyl resin, epoxy resin, urethane resin, cellulose resin, siloxane resin, polyimide resin, polyamide resin, and perylene resin. However, embodiments are not limited thereto. The second insulating layer INS2 and/or the protective layer PVX may include an inorganic material.

FIG. 6 is a schematic cross-sectional view illustrating an embodiment of the display device of FIG. 1.

Referring to FIG. 6, the display device DD may include first, second, and third light emitting layers EL1, EL2, and EL3 emitting light of different colors.

For example, the display device DD may include sub-pixels SPX each forming a sub-pixel area SPXA. The sub-pixel areas SPXA may include a first sub-pixel area SPXA1 where the light of the first color is emitted as an area formed by a first sub-pixel SPX1, a second sub-pixel area SPXA2 where the light of the second color is emitted as an area formed by a second sub-pixel SPX2, and a third sub-pixel area SPXA3 where the light of the third color is emitted as an area formed by a third sub-pixel SPX3.

According to an embodiment, the light of the first color of the first wavelength band may be emitted from the first sub-pixel area SPXA1. The light of the second color of the second wavelength band may be emitted from the second sub-pixel area SPXA2. The light of the third color of the third wavelength band may be emitted from the third sub-pixel area SPXA3.

The second electrode ELT2, the capping layer CAP, the antireflection layer LRL, and the encapsulation layer TFE may be sequentially disposed on the first, second, and third light emitting layers EL1, EL2, and EL3. Each of the second electrode ELT2, the capping layer CAP, the antireflection layer LRL, and the encapsulation layer TFE may be disposed over the sub-pixels SPX.

The sensor unit TSP may be disposed on the encapsulation layer TFE. According to an embodiment, the first conductive pattern layer CP1 and the second conductive pattern layer CP2 included in the sensor unit TSP may form the sensing electrodes SP.

According to an embodiment, a contact portion CNT may be formed in the second insulating layer INS2 included in the sensor unit TSP. The contact portion CNT may pass through the second insulating layer INS2. According to an embodiment, at least a portion of the second conductive pattern layer CP2 may be electrically connected to the first conductive pattern layer CP1 through the contact portion CNT.

The outer portion OUP may be disposed on the sensor unit TSP and may include the light blocking layer BM, the reflection control layer RCL, and the protective film PF.

The light blocking layer BM may be disposed on the protective layer PVX. The light blocking layer BM may contact the protective layer PVX. The light blocking layer BM may contact the reflection control layer RCL. The light blocking layer BM may be disposed between the reflection control layer RCL and the sensor unit TSP.

The light blocking layer BM may be disposed between adjacent sub-pixel areas SPXA. For example, the light blocking layer BM may be disposed between the first sub-pixel arca SPXA1 and the second sub-pixel area SPXA2, may be disposed between the second sub-pixel area SPXA2 and the third sub-pixel area SPXA3, and may be disposed between the first sub-pixel area SPXA1 and the third sub-pixel area SPXA3. According to an embodiment, an opening included in the light blocking layer BM may overlap the sub-pixel arca SPXA in a plan view.

The light blocking layer BM may include a light absorbing material. The light absorbing material may include a colorant including at least one of carbon black and lactam black. However, embodiments are not limited thereto, and the light absorbing material may be implemented with various materials. According to an embodiment, the light blocking layer BM may not include a light blocking structure formed by stacking two or more color filters.

The light blocking layer BM may overlap the first conductive pattern layer CP1 and the second conductive pattern layer CP2 in a plan view. Accordingly, the light blocking layer BM may reduce a risk of damage to visibility by the first conductive pattern layer CP1 and the second conductive pattern layer CP2.

The reflection control layer RCL may be disposed outside the display unit DP based on a display direction (for example, the third direction DR3) of the display device DD. For example, the reflection control layer RCL may be disposed on the sensor unit TSP (for example, the protective layer PVX).

The reflection control layer RCL may include a first surface SF1 and a second surface SF2. The first surface SF1 may be a lower surface of the reflection control layer RCL and may face the display unit DP. The second surface SF2 may be a surface opposite to the first surface SF1. The second surface SF2 may face the outside and may face the protective film PF.

The reflection control layer RCL may contact the light blocking layer BM. The reflection control layer RCL may contact the protective film PF. The reflection control layer RCL may contact an upper surface (for example, the protective layer PVX) of the sensor unit TSP.

The reflection control layer RCL may be disposed over the sub-pixels SPX. The reflection control layer RCL may be disposed over the sub-pixel areas SPXA. For example, the reflection control layer RCL may be included in each of the first sub-pixel SPX1, the second sub-pixel SPX2, and the third sub-pixel SPX3. The reflection control layer RCL may be disposed over the first sub-pixel area SPXA1, the second sub-pixel area SPXA2, and the third sub-pixel area SPXA3. For example, the reflection control layer RCL disposed in each of the first sub-pixel area SPXA1, the second sub-pixel area SPXA2, and the third sub-pixel arca SPXA3 may be integral with each other.

According to an embodiment, light emitted from the light emitting layer EL may pass through the reflection control layer RCL and may be emitted to the outside. According to embodiment, the light emitted from the light emitting layer EL may pass through the capping layer CAP, the antireflection layer LRL, and the reflection control layer RCL and may be output.

For example, light emitted from the first light emitting layer EL1 may pass through the reflection control layer RCL (or the capping layer CAP, the antireflection layer LRL, and the reflection control layer RCL) and may be emitted to the outside of the display device DD. Accordingly, the first sub-pixel area SPXA1 may be formed or defined. Light emitted from the second light emitting layer EL2 may pass through the reflection control layer RCL (or the capping layer CAP, the antireflection layer LRL, and the reflection control layer RCL) and may be emitted to the outside of the display device DD. Accordingly, the second sub-pixel arca SPXA2 may be formed or defined. Light emitted from the third light emitting layer EL3 may pass through the reflection control layer RCL (or the capping layer CAP, the antireflection layer LRL, and the reflection control layer RCL) and may be emitted to the outside of the display device DD. Accordingly, the third sub-pixel area SPXA3 may be formed or defined.

The reflection control layer RCL may selectively absorb light of a wavelength band. Accordingly, the reflection control layer RCL may control a reflectivity of the display device DD, and thus may improve display quality of the display device DD.

The reflection control layer RCL may absorb at least a portion of light of the non-emission wavelength band for the light emitting layer EL.

For example, the reflection control layer RCL may absorb at least a portion of each of first light of the first non-emission wavelength band and second light of the second non-emission wavelength band.

According to an embodiment, the reflection control layer RCL may absorb at least a portion of light having a wavelength of about 460 nm to about 520 nm, and may absorb at least a portion of light having a wavelength of about 560 nm to about 620 nm. In another example, according to an embodiment, the reflection control layer RCL may absorb at least a portion of light having a wavelength of about 490 nm to about 505 nm, and may absorb at least a portion of light having a wavelength of about 585 nm to about 600 nm.

Accordingly, the reflection control layer RCL may absorb at least a portion of the light of the non-emission wavelength band for the light emitting layer EL, and may improve display quality.

The reflection control layer RCL may include various materials. According to an embodiment, the reflection control layer RCL may include a dye, a pigment, or a combination thereof. For example, the reflection control layer RCL may include various organic materials, and the reflection control layer RCL may include one or more of a group of an oxazine-based compound, a cyanine-based compound, a tetraazoporfin-based compound, and a squarylium-based compound. However, embodiments are not limited thereto.

The protective film PF may be disposed on the reflection control layer RCL. The protective film PF may contact the reflection control layer RCL. The protective film PF may be disposed relatively outside the display device DD to protect internal configurations of the display device DD.

According to an embodiment, the protective film PF may include one of a polyethyleneterephthalate (PET) film, a low reflection film, a polarizing film, and a transmittance controllable film. However, embodiments are not limited thereto.

A structure of the outer portion OUP according to an embodiment is not limited to the above-described example. For example, the outer portion OUP may further include a window capable of transmitting light.

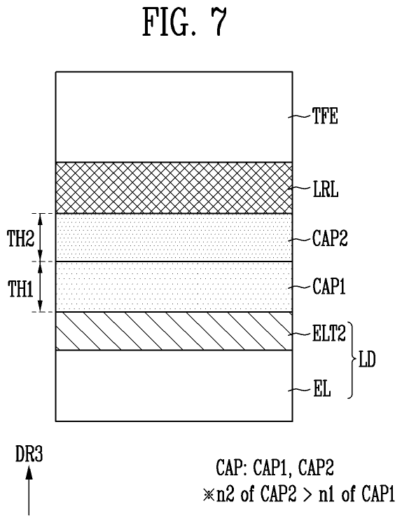

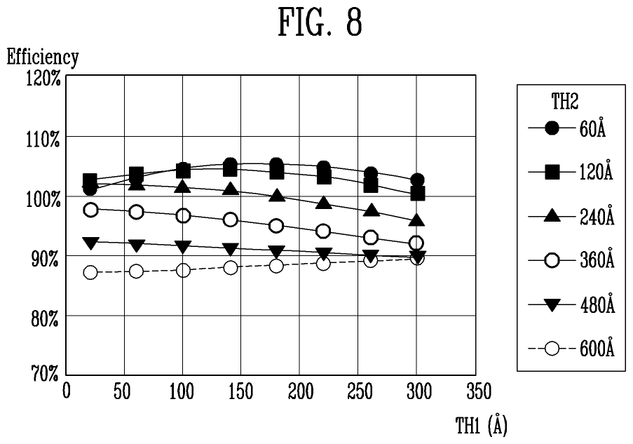

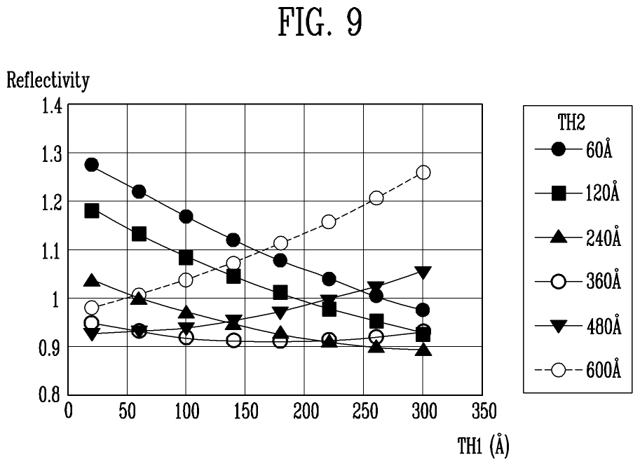

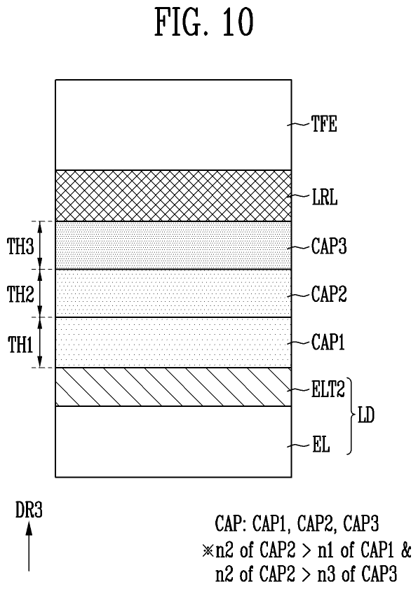

FIG. 7 is a schematic cross-sectional view illustrating an embodiment of the capping layer included in the display device of FIG. 6. For example, the light emitting element LD, the antireflection layer LRL, and the encapsulation layer TFE adjacent to the capping layer CAP are further shown in FIG. 7. FIG. 8 is a schematic diagram illustrating light emission efficiency according to a thickness of the capping layer of FIG. 7. FIG. 9 is a schematic diagram illustrating reflectivity according to the thickness of the capping layer of FIG. 7.

Referring to FIG. 7, the capping layer CAP may include a first capping layer CAP1 and a second capping layer CAP2.

The first capping layer CAP1 may be disposed (e.g., directly disposed) on the light emitting element LD (or the second electrode ELT2), and the second capping layer CAP2 may be disposed on the first capping layer CAP1. The first capping layer CAP1 and the second capping layer CAP2 may include an inorganic material. The capping layer CAP may cancel the external light by using a phase difference of external light reflected from each of the first capping layer CAP1 and the second capping layer CAP2.

In an embodiment, a refractive index n2 of the second capping layer CAP2 may be greater than a refractive index n1 of the first capping layer CAP1. For example, the refractive index n2 of the second capping layer CAP2 may be greater than the refractive index n1 of the first capping layer CAP1 by about 0.1 or more. For example, the refractive index n1 of the first capping layer CAP1 may be within a range of about 1.2 to about 1.7, and the refractive index n2 of the second capping layer CAP2 may be within a range of about 1.7 to about 2.2. For example, the first capping layer CAP1 may be referred to as a low refractive index capping layer, and the second capping layer CAP2 may be referred to as a high refractive index capping layer.

In an embodiment, a thickness TH1 of the first capping layer CAP1 may be in a range of about 20 Å to about 400 Å, and a thickness TH2 of the second capping layer CAP2 may be in a range of about 60 Å to about 400 Å. For example, although light emission efficiency (or efficiency) is improved through the capping layer CAP, reflectivity (or reflectance) of the external light may be reduced.

Referring to FIGS. 7 and 8, FIG. 8 shows light emission efficiency (or efficiency) according to the thickness TH1 of the first capping layer CAP1 for each thickness TH2 of the second capping layer CAP2. The light emission efficiency (or efficiency) shown in FIG. 8 (and light emission efficiency described below) may be a ratio of a light emission amount of the display device DD (refer to FIG. 6) to a light emission amount of a display device that does not include the capping layer CAP. As light emission efficiency increases, display quality may be improved.

As shown in FIG. 8, in case that the thickness TH2 of the second capping layer CAP2 is about 60 Å or about 120 Å, the light emission efficiency may be about 100% or more. In case that the thickness TH2 of the second capping layer CAP2 is about 240 Å and the thickness TH1 of the first capping layer CAP1 is in a range of about 200 Å or less, the light emission efficiency may be in a range of about 98% or more. Since the light emission efficiency according to the thickness TH1 of the first capping layer CAP1 and the thickness TH2 of the second capping layer CAP2 is as shown in FIG. 8, a detailed description of the light emission efficiency for each thickness is omitted for descriptive convenience.

Referring to FIGS. 7 and 9, reflectivity according to the thickness TH1 of the first capping layer CAP1 for each thickness TH2 of the second capping layer CAP2 is shown in FIG. 9. The reflectivity shown in FIG. 9 (and reflectivity described below) may be a ratio of external light reflectivity of the display device DD (refer to FIG. 6) to external light reflectivity of the display device that does not include the capping layer CAP. As the reflectivity decreases, display quality may be improved.

As shown in FIG. 9, in case that the thickness TH2 of the second capping layer CAP2 is about 240 Å and the thickness TH1 of the first capping layer CAP1 is about 60 Å, the reflectivity may be in a range of about 1 or less. In case that the thickness TH2 of the second capping layer CAP2 is about 360 Å, the reflectivity may be in a range of about 1 or less. In case that the thickness TH2 of the second capping layer CAP2 is about 480 Å and the thickness TH1 of the first capping layer CAP1 is in a range of about 220 Å or less, the reflectivity may be in a range of about 1 or less. Since the reflectivity according to the thickness TH1 of the first capping layer CAP1 and the thickness TH2 of the second capping layer CAP2 is as shown in FIG. 9, a detailed description of the reflectivity for each thickness is omitted for descriptive convenience.

In an embodiment, a total thickness of the capping layer CAP including the first capping layer CAP1 and the second capping layer CAP2 may be in a range of about 400 Å to about 450 Å. For example, the thickness TH1 of the first capping layer CAP1 may be in a range of about 180 Å to about 300 Å, and the thickness TH2 of the second capping layer CAP2 may be in a range of about 120 Å to about 240 Å. For example, the reflectivity may be reduced while maintaining the light emission efficiency of about 98% or more.

TABLE 1

| | | | | Light emission |
|---|---|---|---|---|
| Division | TH1 (Å) | TH2 (Å) | Reflectivity | efficiency (%) |
| CASE1 | 260 | 180 | 0.918 (7.25) | 99.61 (78.6) |
| CASE2 | 180 | 240 | 0.927 (7.32) | 99.74 (78.7) |
| CASE3 | 300 | 120 | 0.931 (7.36) | 100.25 (79.1) |

Table 1 illustrates the thicknesses TH1 and TH2, the reflectivity, and the light emission efficiency of the first and second capping layers CAP1 and CAP2 according to the embodiments of FIGS. 7 to 9. A numerical value (or a numerical value written in parentheses) together with the reflectivity may indicate a ratio (or an absolute value) of reflecting the external light, and a numerical value written together with the light emission efficiency may indicate an efficiency ratio (or a light emission efficiency ratio) of the display device DD of FIG. 6 compared to a display device using a polarizing film instead of the outer portion OUP of FIG. 6 (or the reflection control layer RCL). For reference, the ratio and the efficiency ratio of reflecting the external light by the display device that does not include the capping layer CAP may be in a range of about 7.90 and about 78.9%, respectively.

In the first case CASE1, in case that the thickness TH1 of the first capping layer CAP1 is about 260 Å and the thickness TH2 of the second capping layer CAP2 is about 180 Å, the reflectivity may be about 0.918 and the light emission efficiency may be about 99.61%.

In the second case CASE2, in case that the thickness TH1 of the first capping layer CAP1 is about 180 Å and the thickness TH2 of the second capping layer CAP2 is about 240 Å, the reflectivity may be about 0.927 and the light emission efficiency may be in a range of about 99.74%.

In the third case CASE3, in case that the thickness TH1 of the first capping layer CAP1 is about 300 Å and the thickness TH2 of the second capping layer CAP2 is about 120 Å, the reflectivity may be about 0.931 and the light emission efficiency may be about 100.25%.

As described above, the capping layer CAP may include the first capping layer CAP1 and the second capping layer CAP2, the refractive index n2 of the second capping layer CAP2 may be greater than the refractive index n1 of the first capping layer CAP1, the thickness TH1 of the first capping layer CAP1 may be in a range of about 20 Å to about 400 Å, and the thickness TH2 of the second capping layer CAP2 may be in a range of about 60 Å to about 400 Å. For example, while maintaining the light emission efficiency of the display device DD (refer to FIG. 6), the reflectivity of the external light may be reduced, and display quality of the display device DD may be improved.

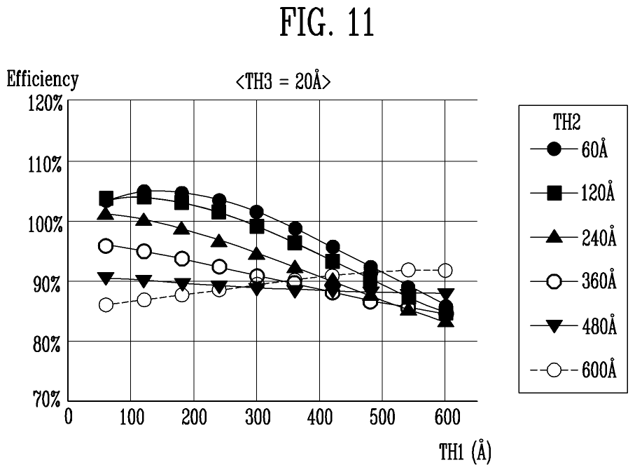

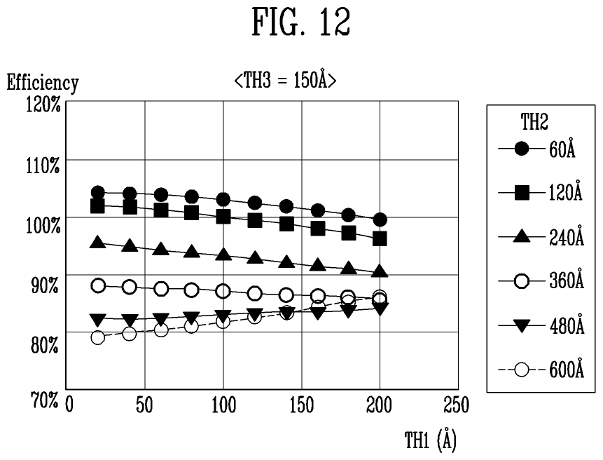

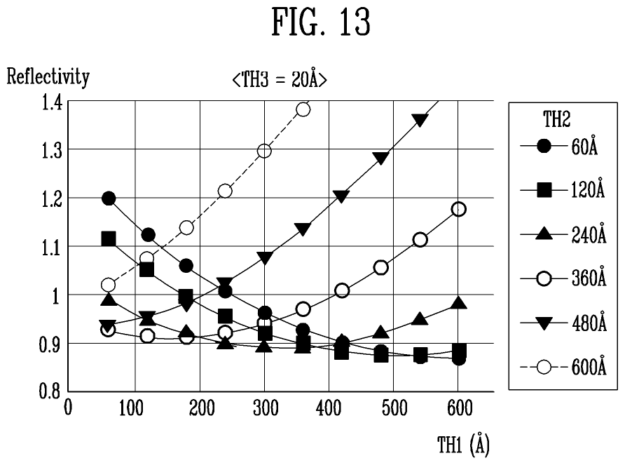

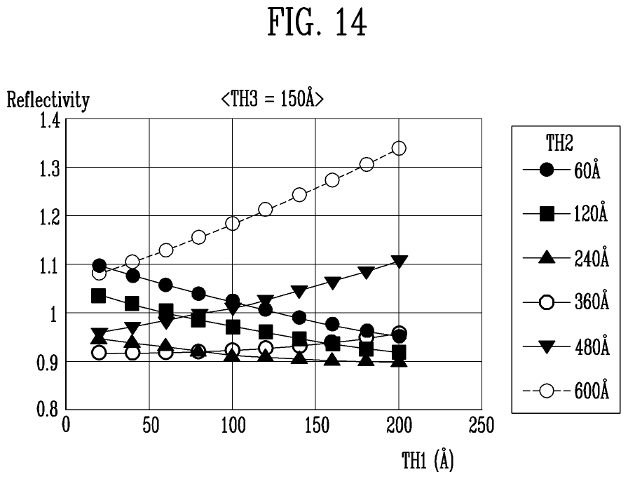

FIG. 10 is a schematic cross-sectional view illustrating an embodiment of the capping layer included in the display device of FIG. 6. For example, the light emitting element LD, the antireflection layer LRL, and the encapsulation layer TFE adjacent to the capping layer CAP are further shown in FIG. 10. FIGS. 11 and 12 are schematic diagrams illustrating light emission efficiency according to a thickness of the capping layer of FIG. 10. FIGS. 13 and 14 are schematic diagrams illustrating reflectivity according to the thickness of the capping layer of FIG. 10.

Referring to FIGS. 7 and 10, the capping layer CAP may further include a third capping layer CAP3. For example, the capping layer CAP may include the first capping layer CAP1, the second capping layer CAP2, and the third capping layer CAP3. The capping layer CAP may cancel (or eliminate) the external light by using a phase difference of external light reflected from each of the first capping layer CAP1, the second capping layer CAP2, and the third capping layer CAP3.

The third capping layer CAP3 may be disposed on the second capping layer CAP2. The third capping layer CAP3 may be disposed between the second capping layer CAP2 and the antireflection layer LRL. The third capping layer CAP3 may include an inorganic material.

In an embodiment, the refractive index n2 of the second capping layer CAP2 may be greater than each of the refractive index n1 of the first capping layer CAP1 and a refractive index n3 of the third capping layer CAP3. For example, the refractive index n2 of the second capping layer CAP2 may be greater than each of the refractive index n1 of the first capping layer CAP1 and the refractive index n3 of the third capping layer CAP3 by about 0.1 or more. For example, each of the refractive index n1 of the first capping layer CAP1 and the refractive index n3 of the third capping layer CAP3 may be within a range of about 1.2 to about 1.7, and the refractive index n2 of the second capping layer CAP2 may be within a range of about 1.7 to about 2.2. For example, the first capping layer CAP1 may be referred to as a first low refractive index capping layer, the second capping layer CAP2 may be referred to as a high refractive index capping layer, and the third capping layer CAP3 may be referred to as a second low refractive index capping layer.

In an embodiment, the thickness TH1 of the first capping layer CAP1 may be in a range of about 20 Å to about 400 Å, the thickness TH2 of the second capping layer CAP2 may be in a range of about 60 Å to about 400 Å, and a thickness TH3 of the third capping layer CAP3 may be in a range of about 20 Å to about 300 Å. For example, although the light emission efficiency (or the efficiency) is maintained or improved through the capping layer CAP, the reflectivity (or the reflectance) of the external light may be reduced.

Referring to FIG. 11, the light emission efficiency (or the efficiency) according to the thickness TH1 of the first capping layer CAP1 is shown for each thickness TH2 of the second capping layer CAP2 in case that the thickness TH3 of the third capping layer CAP3 is about 20 Å.

As shown in FIG. 11, in case that the thickness TH3 of the third capping layer CAP3 is about 20 Å, and in case that the thickness TH2 of the second capping layer CAP2 is less than about 120 Å and the thickness TH1 of the first capping layer CAP1 is less than about 300 Å, the light emission efficiency may be in a range of about 100% or more. In case that the thickness TH3 of the third capping layer CAP3 is about 20 Å, and in case that the thickness of the second capping layer CAP2 is about 240 Å and the thickness TH1 of the first capping layer CAP1 is less than about 200 Å, the light emission efficiency may be in a range of about 98% or more. In case that the thickness TH3 of the third capping layer CAP3 is about 20 Å, the light emission efficiency according to the thickness TH1 of the first capping layer CAP1 and the thickness TH2 of the second capping layer CAP2 is as shown in FIG. 11, and thus a detailed description of the light emission efficiency for each thickness is omitted for descriptive convenience.

Referring to FIG. 12, the light emission efficiency (or the efficiency) according to the thickness TH1 of the first capping layer CAP1 is shown for each thickness TH2 of the second capping layer CAP2 in case that the thickness TH3 of the third capping layer CAP3 is about 150 Å.

As shown in FIG. 12, in case that the thickness TH3 of the third capping layer CAP3 is about 150 Å, and in case that the thickness TH2 of the second capping layer CAP2 is about 60 Å, the light emission efficiency may be in a range of about 100% or more. In case that the thickness TH3 of the third capping layer CAP3 is about 150 Å, and in case that the thickness of the second capping layer CAP2 is about 120 Å and the thickness TH1 of the first capping layer CAP1 is less than about 100 Å, the light emission efficiency may be in a range of about 100% or more. In case that the thickness TH3 of the third capping layer CAP3 is about 150 Å, the light emission efficiency according to the thickness TH1 of the first capping layer CAP1 and the thickness TH2 of the second capping layer CAP2 is as shown in FIG. 12, and thus a detailed description of the light emission efficiency for each thickness is omitted for descriptive convenience.

Referring to FIG. 13, the reflectivity according to the thickness TH1 of the first capping layer CAP1 is shown for each thickness TH2 of the second capping layer CAP2 in case that the thickness TH3 of the third capping layer CAP3 is about 20 Å.

As shown in FIG. 13, in case that the thickness TH3 of the third capping layer CAP3 is about 20 Å, and in case that the thickness TH2 of the second capping layer CAP2 is in a range of about 120 Å or less and the thickness TH1 of the first capping layer CAP1 is in a range of about 200 Å or more, the reflectivity may be in a range of about 1 or less. In case that the thickness TH3 of the third capping layer CAP3 is about 20 Å, and in case that the thickness TH2 of the second capping layer CAP2 is about 240 Å, the reflectivity may be in a range of about 1 or less. In case that the thickness TH3 of the third capping layer CAP3 is about 20 Å, and in case that the thickness TH2 of the second capping layer CAP2 is about 360 Å and the thickness TH1 of the first capping layer CAP1 is in a range of about 400 Å or less, the reflectivity may be in a range of about 1 or less. In case that the thickness TH3 of the third capping layer CAP3 is about 20 Å, the reflectivity according to the thickness TH1 of the first capping layer CAP1 and the thickness TH2 of the second capping layer CAP2 is as shown in FIG. 13, and thus a detailed description of the reflectivity for each thickness is omitted for descriptive convenience.

Referring to FIG. 14, the reflectivity according to the thickness TH1 of the first capping layer CAP1 is shown for each thickness TH2 of the second capping layer CAP2 in case that the thickness TH3 of the third capping layer CAP3 is about 150 Å.

As shown in FIG. 14, in case that the thickness TH3 of the third capping layer CAP3 is about 150 Å, and in case that the thickness TH2 of the second capping layer CAP2 is about 60 Å and the thickness TH1 of the first capping layer CAP1 is in a range of about 100 Å or more, the reflectivity may be in a range of about 1 or less. In case that the thickness TH3 of the third capping layer CAP3 is about 150 Å, and in case that the thickness TH2 of the second capping layer CAP2 is about 240 Å or 360 Å, the reflectivity may be in a range of about 1 or less. In case that the thickness TH3 of the third capping layer CAP3 is about 150 Å, and in case that the thickness TH2 of the second capping layer CAP2 is about 480 Å and the thickness TH1 of the first capping layer CAP1 is in a range of about 100 Å or less, the reflectivity may be in a range of about 1 or less. In case that the thickness TH3 of the third capping layer CAP3 is about 150 Å, the reflectivity according to the thickness TH1 of the first capping layer CAP1 and the thickness TH2 of the second capping layer CAP2 is as shown in FIG. 14, and thus a detailed description of the reflectivity for each thickness is omitted for descriptive convenience.

In an embodiment, a total thickness of the capping layer CAP including the first capping layer CAP1, the second capping layer CAP2, and the third capping layer CAP3 may be in a range of about 400 Å to about 450 Å. For example, the thickness TH1 of the first capping layer CAP1 may be in a range of about 180 Å to about 300 Å, the thickness TH2 of the second capping layer CAP2 may be in a range of about 60 Å to about 180 Å, and the thickness TH3 of the third capping layer CAP3 may be in a range of about 20 Å to about 150 Å. For example, reflectivity may be reduced while maintaining the light emission efficiency of a range of about 98% or more.

TABLE 2

| | | | | | Light emission |
|---|---|---|---|---|---|
| Division | TH1(Å) | TH2(Å) | TH3(Å) | Reflectivity | efficiency (%) |
| CASE1 | 300 | 120 | 20 | 0.922 (7.29) | 99.23 (78.3) |
| CASE2 | 240 | 180 | 20 | 0.920 (7.27) | 99.23 (78.3) |
| CASE3 | 200 | 180 | 40 | 0.931 (7.36) | 99.49 (78.5) |
| CASE4 | 240 | 120 | 60 | 0.935 (7.39) | 99.61 (78.6) |
| CASE5 | 180 | 120 | 100 | 0.950 (7.51) | 99.87 (78.8) |
| CASE6 | 200 | 60 | 150 | 0.951 (7.52) | 99.49 (78.5) |

Table 2 illustrates the thicknesses TH1, TH2, and TH3, the reflectivity, and the light emission efficiency of the first, second, and third capping layers CAP1, CAP2, and CAP3 according to the embodiments of FIGS. 10 to 14. A numerical value written together with the reflectivity may indicate a ratio (or an absolute value) of reflecting the external light, and a numerical value written together with the light emission efficiency may indicate an efficiency ratio (or a light emission efficiency ratio) of the display device DD of FIG. 6 compared to a display device using a polarizing film instead of the outer portion OUP of FIG. 6 (or the reflection control layer RCL).

In the first case CASE1, in case that the thickness TH1 of the first capping layer CAP1 is about 300 Å, the thickness TH2 of the second capping layer CAP2 is about 120 Å, and the thickness TH3 of the third capping layer CAP3 is about 20 Å, the reflectivity may be about 0.922 and the light emission efficiency may be about 99.23%.

In the second case CASE2, in case that the thickness TH1 of the first capping layer CAP1 is about 240 Å, the thickness TH2 of the second capping layer CAP2 is about 180 Å, and the thickness TH3 of the third capping layer CAP3 is about 20 Å, the reflectivity may be about 0.920 and the light emission efficiency may be about 99.23%.

The thicknesses TH1, TH2, and TH3 of the first, second, and third capping layers CAP1, CAP2, and CAP3 and the reflectivity and light emission efficiency according thereto, according to each of the third case CASE3, the fourth case CASE4, the fifth case CASE5, and the sixth case CASE6 are as described in Table 2, and thus a detailed description of the third to sixth cases CASE3 to CASE6 is omitted.

As described above, the capping layer CAP may include the first capping layer CAP1, the second capping layer CAP2, and the third capping layer CAP3, and the refractive index n2 of the second capping layer CAP2 may be greater than each of the refractive index n1 of the first capping layer CAP1 and the refractive index n3 of the third capping layer CAP3. For example, the thickness TH1 of the first capping layer CAP1 may be in a range of about 20 Å to about 400 Å, the thickness TH2 of the second capping layer CAP2 may be in a range of about 60 Å to about 400 Å, and the thickness TH3 of the third capping layer CAP3 may be in a range of about 20 Å to about 300 Å. While maintaining the light emission efficiency of the display device DD (refer to FIG. 6), the reflectivity of the external light may be reduced, and display quality of the display device DD may be improved.

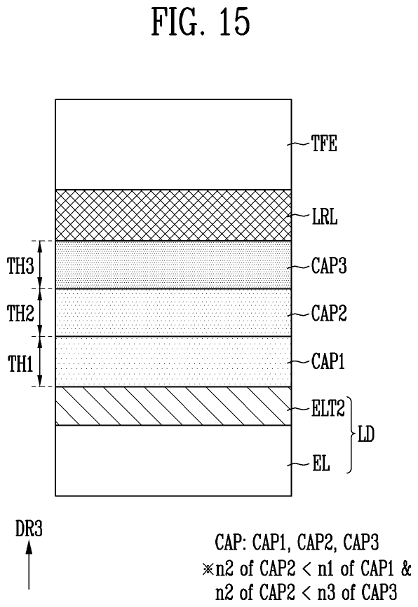

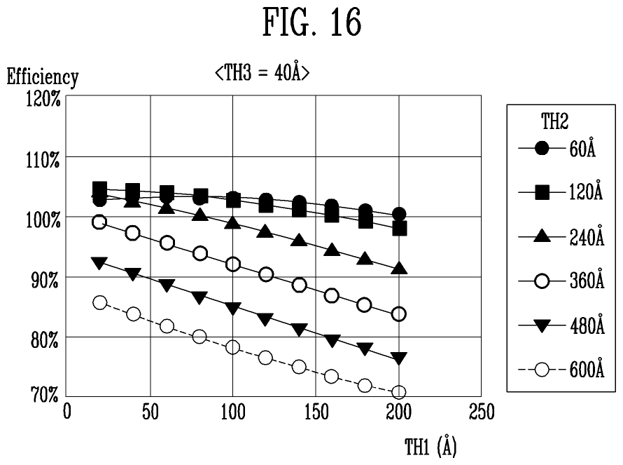

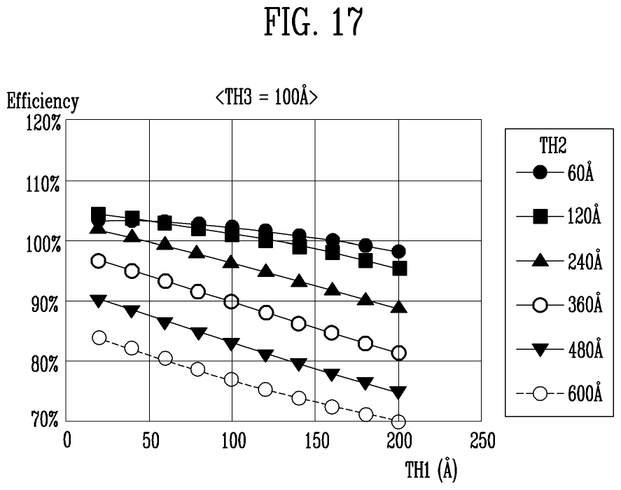

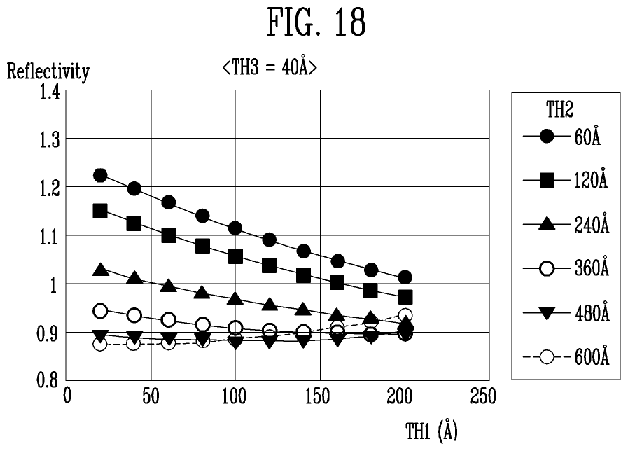

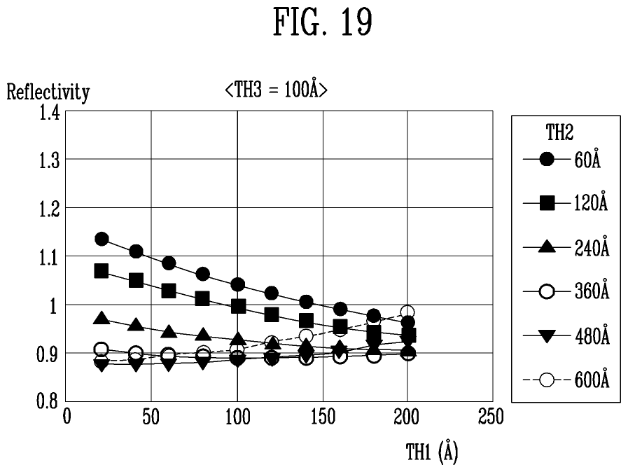

FIG. 15 is a schematic cross-sectional view illustrating an embodiment of the capping layer included in the display device of FIG. 6. For example, the light emitting element LD, the antireflection layer LRL, and the encapsulation layer TFE adjacent to the capping layer CAP are further shown in FIG. 15. FIGS. 16 and 17 are schematic diagrams illustrating light emission efficiency according to a thickness of the capping layer of FIG. 15. FIGS. 18 and 19 are schematic diagrams illustrating reflectivity according to the thickness of the capping layer of FIG. 15.

Referring to FIG. 15, the capping layer CAP may include the first capping layer CAP1, the second capping layer CAP2, and the third capping layer CAP3. Since a structure and a function of the capping layer CAP are described with reference to FIG. 10, a description thereof is omitted for descriptive convenience.

In an embodiment, the refractive index n2 of the second capping layer CAP2 may be less than each of the refractive index n1 of the first capping layer CAP1 and the refractive index n3 of the third capping layer CAP3. For example, the refractive index n2 of the second capping layer CAP2 may be less than each of the refractive index n1 of the first capping layer CAP1 and the refractive index n3 of the third capping layer CAP3 by about 0.1 or more. For example, each of the refractive index n1 of the first capping layer CAP1 and the refractive index n3 of the third capping layer CAP3 may be within a range of about 1.7 to about 2.2, and the refractive index n2 of the second capping layer CAP2 may be within a range of about 1.2 to about 1.7. For example, the first capping layer CAP1 may be referred to as a first high refractive index capping layer, the second capping layer CAP2 may be referred to as a low refractive index capping layer, and the third capping layer CAP3 may be referred to as a second high refractive index capping layer.

In an embodiment, the thickness TH1 of the first capping layer CAP1 may be in a range of about 20 Å to about 300 Å, the thickness TH2 of the second capping layer CAP2 may be in a range of about 60 Å to about 400 Å, and the thickness TH3 of the third capping layer CAP3 may be in a range of about 20 Å to about 300 Å. For example, although the light emission efficiency (or the efficiency) is maintained or improved through the capping layer CAP, the reflectivity (or the reflectance) of the external light may be reduced.

Referring to FIG. 16, the light emission efficiency (or the efficiency) according to the thickness TH1 of the first capping layer CAP1 is shown for each thickness TH2 of the second capping layer CAP2 in case that the thickness TH3 of the third capping layer CAP3 is about 40 Å.

As shown in FIG. 16, in case that the thickness TH3 of the third capping layer CAP3 is about 40 Å, and in case that the thickness TH2 of the second capping layer CAP2 is less than about 120 Å and the thickness TH1 of the first capping layer CAP1 is less than about 200 Å, the light emission efficiency may be in a range of about 100% or more. In case that the thickness TH3 of the third capping layer CAP3 is about 40 Å, and in case that the thickness of the second capping layer CAP2 is about 240 Å and the thickness TH1 of the first capping layer CAP1 is less than about 100 Å, the light emission efficiency may be in a range of about 98% or more. In case that the thickness TH3 of the third capping layer CAP3 is about 40 Å, the light emission efficiency according to the thickness TH1 of the first capping layer CAP1 and the thickness TH2 of the second capping layer CAP2 is as shown in FIG. 16, and thus a detailed description of the light emission efficiency for each thickness is omitted for descriptive convenience.

Referring to FIG. 17, the light emission efficiency (or the efficiency) according to the thickness TH1 of the first capping layer CAP1 is shown for each thickness TH2 of the second capping layer CAP2 in case that the thickness TH3 of the third capping layer CAP3 is about 100 Å.

As shown in FIG. 17, in case that the thickness TH3 of the third capping layer CAP3 is about 100 Å, and in case that the thickness TH2 of the second capping layer CAP2 is about 60 Å, the light emission efficiency may be in a range of about 100% or more. In case that the thickness TH3 of the third capping layer CAP3 is about 100 Å, and in case that the thickness of the second capping layer CAP2 is about 120 Å and the thickness TH1 of the first capping layer CAP1 is less than about 150 Å, the light emission efficiency may be in a range of about 98% or more. In case that the thickness TH3 of the third capping layer CAP3 is about 100 Å, the light emission efficiency according to the thickness TH1 of the first capping layer CAP1 and the thickness TH2 of the second capping layer CAP2 is as shown in FIG. 17, and thus a detailed description of the light emission efficiency for each thickness is omitted for descriptive convenience.

Referring to FIG. 18, the reflectivity according to the thickness TH1 of the first capping layer CAP1 is shown for each thickness TH2 of the second capping layer CAP2 in case that the thickness TH3 of the third capping layer CAP3 is about 40 Å.

As shown in FIG. 18, in case that the thickness TH3 of the third capping layer CAP3 is about 40 Å, and in case that the thickness TH2 of the second capping layer CAP2 is about 120 Å and the thickness TH1 of the first capping layer CAP1 is in a range of about 150 Å or more, the reflectivity may be in a range of about 1 or less. In case that the thickness TH3 of the third capping layer CAP3 is about 40 Å, and in case that the thickness TH2 of the second capping layer CAP2 is in a range of about 240 Å or more, the reflectivity may be in a range of about 1 or less. In case that the thickness TH3 of the third capping layer CAP3 is about 40 Å, the reflectivity according to the thickness TH1 of the first capping layer CAP1 and the thickness TH2 of the second capping layer CAP2 is as shown in FIG. 18, and thus a detailed description of the reflectivity for each thickness is omitted for descriptive convenience.

Referring to FIG. 19, the reflectivity according to the thickness TH1 of the first capping layer CAP1 is shown for each thickness TH2 of the second capping layer CAP2 in case that the thickness TH3 of the third capping layer CAP3 is about 100 Å.

As shown in FIG. 19, in case that the thickness TH3 of the third capping layer CAP3 is about 100 Å, and in case that the thickness TH2 of the second capping layer CAP2 is about 120 Å or less and the thickness TH1 of the first capping layer CAP1 is in a range of about 100 Å or more, the reflectivity may be in a range of about 1 or less. In case that the thickness TH3 of the third capping layer CAP3 is about 100 Å, and in case that the thickness TH2 of the second capping layer CAP2 is in a range of about 240 Å or more, the reflectivity may be in a range of about 1 or less. In case that the thickness TH3 of the third capping layer CAP3 is about 100 Å, the reflectivity according to the thickness TH1 of the first capping layer CAP1 and the thickness TH2 of the second capping layer CAP2 is as shown in FIG. 19, and thus a detailed description of the reflectivity for each thickness is omitted for descriptive convenience.

In an embodiment, a total thickness of the capping layer CAP including the first capping layer CAP1, the second capping layer CAP2, and the third capping layer CAP3 may be in a range of about 350 Å to about 450 Å. For example, the thickness TH1 of the first capping layer CAP1 may be in a range of about 20 Å to about 240 Å, the thickness TH2 of the second capping layer CAP2 may be in a range of about 120 Å to about 360 Å, and the thickness TH3 of the third capping layer CAP3 may be in a range of about 20 Å to about 200 Å. For example, reflectivity may be reduced while maintaining the light emission efficiency of a range of about 98% or more.

TABLE 3

| | | | | | Light emission |
|---|---|---|---|---|---|
| Division | TH1(Å) | TH2(Å) | TH3(Å) | Reflectivity | efficiency (%) |
| CASE1 | 20 | 360 | 20 | 0.959 (7.58) | 99.74 (78.7) |
| CASE2 | 20 | 360 | 40 | 0.943 (7.45) | 98.98 (78.1) |
| CASE3 | 200 | 120 | 60 | 0.958 (7.57) | 100.38 (79.2) |
| CASE4 | 240 | 120 | 60 | 0.960 (7.59) | 99.74 (78.7) |
| CASE5 | 20 | 300 | 100 | 0.934 (7.38) | 99.49 (78.5) |
| CASE6 | 40 | 180 | 200 | 0.927 (7.33) | 98.85 (78.0) |

Table 3 illustrates the thicknesses TH1, TH2, and TH3, the reflectivity, and the light emission efficiency of the first, second, and third capping layers CAP1, CAP2, and CAP3 according to the embodiments of FIGS. 15 to 19. A numerical value written together with the reflectivity may indicate a ratio (or an absolute value) of reflecting the external light, and a numerical value written together with the light emission efficiency may indicate an efficiency ratio (or a light emission efficiency ratio) of the display device DD of FIG. 6 compared to a display device using a polarizing film instead of the outer portion OUP of FIG. 6 (or the reflection control layer RCL).

In the first case CASE1, in case that the thickness TH1 of the first capping layer CAP1 is about 20 Å, the thickness TH2 of the second capping layer CAP2 is about 360 Å, and the thickness TH3 of the third capping layer CAP3 is about 20 Å, the reflectivity may be about 0.959 and the light emission efficiency may be about 99.74%.

In the second case CASE2, in case that the thickness TH1 of the first capping layer CAP1 is about 20 Å, the thickness TH2 of the second capping layer CAP2 is about 360 Å, and the thickness TH3 of the third capping layer CAP3 is about 40 Å, the reflectivity may be about 0.943 and the light emission efficiency may be about 98.98%.

The thicknesses TH1, TH2, and TH3 of the first, second, and third capping layers CAP1, CAP2, and CAP3 and the reflectivity and light emission efficiency according thereto, according to each of the third case CASE3, the fourth case CASE4, the fifth case CASE5, and the sixth case CASE6 are as described in Table 3, and thus a detailed description of the third to sixth cases CASE3 to CASE6 is omitted for descriptive convenience.

As described above, the capping layer CAP may include the first capping layer CAP1, the second capping layer CAP2, and the third capping layer CAP3, and the refractive index n2 of the second capping layer CAP2 may be less than each of the refractive index n1 of the first capping layer CAP1 and the refractive index n3 of the third capping layer CAP3. For example, the thickness TH1 of the first capping layer CAP1 may be in a range of about 20 Å to about 240 Å, the thickness TH2 of the second capping layer CAP2 may be in a range of about 120 Å to about 360 Å, and the thickness TH3 of the third capping layer CAP3 may be in a range of about 20 Å to about 200 Å. While maintaining the light emission efficiency of the display device DD (refer to FIG. 6), the reflectivity of the external light may be reduced, and display quality of the display device DD may be improved.

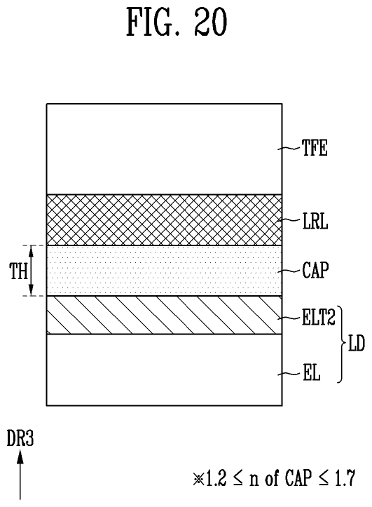

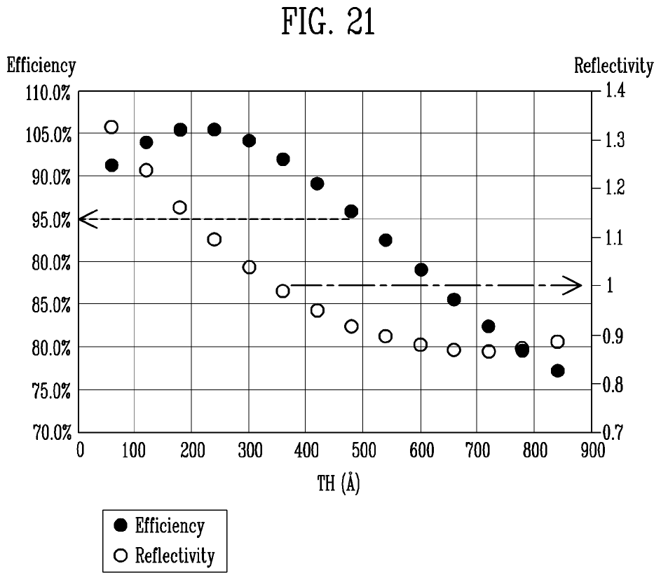

FIG. 20 is a schematic cross-sectional view illustrating an embodiment of the capping layer included in the display device of FIG. 6. For example, the light emitting element LD, the antireflection layer LRL, and the encapsulation layer TFE adjacent to the capping layer CAP are further shown in FIG. 20. FIG. 21 is a schematic diagram illustrating light emission efficiency and reflectivity according to a thickness of the capping layer of FIG. 20.

Referring to FIGS. 3, 6, and 20, since the structure and the function of the capping layer CAP are described with reference to FIG. 3, a description thereof is omitted for descriptive convenience.

In an embodiment, a refractive index n of the capping layer CAP (or the first capping layer) may be within a range of about 1.2 to about 1.7. A refractive index of a general capping layer disposed on the second electrode ELT2 to protect the second electrode ELT2 may be in a range of about 1.8 or more. The capping layer CAP having the refractive index n within the range of about 1.2 to about 1.7 may be referred to as a low refractive index capping layer.

In an embodiment, a thickness TH of the capping layer CAP may be in a range of about 200 Å to about 600 Å. For example, although the light emission efficiency (or the efficiency) is maintained or improved through the capping layer CAP, the reflectivity (or the reflectance) of the external light may be reduced.

As shown in FIG. 21, in case that the thickness TH of the capping layer CAP is in a range of about 600 Å or less, the light emission efficiency may be in a range of about 90% or more. In case that the thickness TH of the capping layer CAP is in a range of about 500 Å or less, the light emission efficiency may be in a range of about 95% or more. As the thickness TH of the capping layer CAP decreases, the light emission efficiency may substantially increase. In case that the thickness TH of the capping layer CAP is about 200 Å, the light emission efficiency may be maximized.

For example, in case that the thickness TH of the capping layer CAP is in a range of about 350 Å or more, the reflectivity may be in a range of about 1 or less. As the thickness TH of the capping layer CAP increases, the reflectivity may substantially decrease. In case that the thickness TH of the capping layer CAP is about 700 Å, the reflectivity may be minimized.

In an embodiment, the thickness of the capping layer CAP may be in a range of about 360 Å to about 480 Å. For example, the reflectivity may be reduced while maintaining the light emission efficiency of a range of about 95% or more.

TABLE 4

| | | | Light emission |
|---|---|---|---|
| Division | TH (Å) | Reflectivity | efficiency (%) |
| CASE1 | 360 | 0.991 (7.83) | 102.02 (80.5) |
| CASE2 | 420 | 0.951 (7.52) | 99.23 (78.3) |
| CASE3 | 480 | 0.920 (7.27) | 95.94 (75.7) |

Table 4 illustrates the thickness TH, the reflectivity, and the light emission efficiency of the capping layer CAP according to the embodiments of FIGS. 20 and 21. A numerical value (or a numerical value written in parentheses) written together with the reflectivity may indicate a ratio (or an absolute value) of reflecting the external light, and a numerical value written together with the light emission efficiency may indicate an efficiency ratio (or a light emission efficiency ratio) of the display device DD of FIG. 6 compared to a display device using a polarizing film instead of the outer portion OUP of FIG. 6 (or the reflection control layer RCL).

In the first case CASE1, in case that the thickness TH of the capping layer CAP is about 360 Å, the reflectivity may be about 0.991 and the light emission efficiency may be about 102.02%.

In the second case CASE2, in case that the thickness TH of the capping layer CAP is about 420 Å, the reflectivity may be about 0.951 and the light emission efficiency may be about 99.23%.

In the third case CASE3, in case that the thickness TH of the capping layer CAP is about 480 Å, the reflectivity may be about 0.920 and the light emission efficiency may be about 95.94%.

As described above, the refractive index n of the capping layer CAP may be within a range of about 1.2 to about 1.7, and the thickness TH of the capping layer CAP may be in a range of about 200 Å to about 600 Å. For example, while maintaining the light emission efficiency of the display device DD (refer to FIG. 6), the reflectivity of the external light may be reduced, and display quality of the display device DD may be improved.

In FIG. 20, another capping layer (for example, the second capping layer or a high refractive index capping layer) may be disposed on at least one of the upper surface (or a first surface) and the lower surface (or a second surface) of the capping layer CAP (or the first capping layer). For example, the high refractive index capping layer may be disposed on the capping layer CAP, and may be the same as the embodiment of FIG. 7 or FIG. 10. As another example, the high refractive index capping layer may be disposed under the capping layer CAP, and may be the same as the embodiment of FIG. 15.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a light emitting element disposed on a substrate;
a capping layer disposed on the light emitting element;
an antireflection layer disposed on the capping layer; and
an encapsulation layer disposed on the antireflection layer,
wherein the capping layer comprises:
a first capping layer disposed on the light emitting element; and
a second capping layer disposed on the first capping layer and having a refractive index greater than a refractive index of the first capping layer, a thickness of the first capping layer is in a range of about 20 Å to about 400 Å, and a thickness of the second capping layer is in a range of about 60 Å to about 400 Å.

2. The display device according to claim 1, wherein
the antireflection layer includes ytterbium or bismuth, and
the first capping layer and the second capping layer include an inorganic material.

3. The display device according to claim 1, wherein a total thickness of the capping layer is in a range of about 400 Å to about 450 Å.

4. The display device according to claim 1, wherein
the refractive index of the second capping layer is greater than the refractive index of the first capping layer by about 0.1 or more,
the refractive index of the first capping layer is in a range of about 1.2 to about 1.7, and
the refractive index of the second capping layer is in a range of about 1.7 to about 2.2.

5. The display device according to claim 1, wherein
the thickness of the first capping layer is in a range of about 180 Å to about 300 Å, and
the thickness of the second capping layer is in a range of about 120 Å to about 240 Å.

6. The display device according to claim 5, wherein a total thickness of the first capping layer and the second capping layer is in a range of about 400 Å to about 450 Å.

7. The display device according to claim 1, wherein
the capping layer further comprises a third capping layer disposed between the second capping layer and the antireflection layer and having a refractive index less than the refractive index of the second capping layer, and
a thickness of the third capping layer is in a range of about 20 Å to about 300 Å.

8. The display device according to claim 7, wherein
the refractive index of the second capping layer is greater than the refractive index of each of the first capping layer and the third capping layer by about 0.1 or more,
the refractive index of the first capping layer is in a range of about 1.2 to about 1.7,
the refractive index of the second capping layer is in a range of about 1.7 to about 2.2, and
the refractive index of the third capping layer is in a range of about 1.2 to about 1.7.

9. The display device according to claim 7, wherein
the thickness of the first capping layer is in a range of about 180 Å to about 300 Å,
the thickness of the second capping layer is in a range of about 60 Å to about 180 Å, and
the thickness of the third capping layer is in a range of about 20 Å to about 150 Å.

10. The display device according to claim 9, wherein a total thickness of the first capping layer, the second capping layer, and the third capping layer is in a range of about 400 Å to about 450 Å.

11. The display device according to claim 1, wherein
the light emitting element comprises:
a first electrode;
a light emitting layer disposed on the first electrode; and
a second electrode disposed on the light emitting layer, and
the capping layer is disposed between the second electrode and the antireflection layer.

12. A display device comprising:
a light emitting element disposed on a substrate;
a capping layer disposed on the light emitting element;
an antireflection layer disposed on the capping layer; and
an encapsulation layer disposed on the antireflection layer,
wherein the capping layer comprises:
a first capping layer disposed on the light emitting element;
a second capping layer disposed on the first capping layer and having a refractive index less than a refractive index of the first capping layer; and
a third capping layer disposed on the second capping layer and having a refractive index greater the refractive index of the second capping layer,
a thickness of the first capping layer is in a range of about 20 Å to about 300 Å,
a thickness of the second capping layer is in a range of about 60 Å to about 400 Å, and
a thickness of the third capping layer is in a range of about 20 Å to about 300 Å.

13. The display device according to claim 12, wherein
the refractive index of the second capping layer is less than the refractive index of each of the first capping layer and the third capping layer by about 0.1 or more,
the refractive index of the first capping layer is in a range of about 1.7 to about 2.2,
the refractive index of the second capping layer is in a range of about 1.2 to about 1.7, and
the refractive index of the third capping layer is in a range of about 1.7 to about 2.2.

14. The display device according to claim 12, wherein
the thickness of the first capping layer is in a range of about 20 Å to about 240 Å,
the thickness of the second capping layer is in a range of about 120 Å to about 360 Å, and
the thickness of the third capping layer is in a range of about 20 Å to about 200 Å.

15. The display device according to claim 14, wherein a total thickness of the capping layer is in a range of about 350 Å to about 450 Å.

16. The display device according to claim 12, wherein
the light emitting element comprises:
a first electrode;
a light emitting layer disposed on the first electrode; and
a second electrode disposed on the light emitting layer, and
the capping layer is disposed between the second electrode and the antireflection layer.

17. A display device comprising:
a light emitting element disposed on a substrate;
a first capping layer disposed on the light emitting element;
an antireflection layer disposed on the first capping layer; and
an encapsulation layer disposed on the antireflection layer, wherein
a refractive index of the first capping layer is in a range of about 1.2 to about 1.7, and
a thickness of the first capping layer is in a range of about 200 Å to about 600 Å.

18. The display device according to claim 17, wherein a thickness of the first capping layer is in a range of about 360 Å to about 480 Å.

19. The display device according to claim 17, wherein
the light emitting element comprises:
a first electrode;
a light emitting layer disposed on the first electrode; and
a second electrode disposed on the light emitting layer, and
the first capping layer is disposed between the second electrode and the antireflection layer.

20. The display device according to claim 17, further comprising:
a second capping layer disposed on at least one of first and second surfaces of the first capping layer, wherein
a refractive index of the second capping layer is greater than the refractive index of the first capping layer by about 0.1 or more, and
the refractive index of the second capping layer is in a range of about 1.7 to about 2.2.
